(19) United States
(12) Patent Application Publication
(10) Pub. No.: US 2017/0108181 A1
(43) Pub. Date: Apr. 20, 2017

(54) LIGHTING DEVICE FOR GENERATING WHITE LIGHT

(71) Applicant: TRIDONIC JENNERSDORF GMBH, Jennersdorf (AT)

(72) Inventor: Janos DOBOS, Szombathely (HU)

(73) Assignee: TRIDONIC JENNERSDORF GMBH, Jennersdorf (AT)

(21) Appl. No.: 15/128,325

(22) PCT Filed: Mar. 17, 2015
(86) PCT No.: PCT/EP2015/055540

§ 371 Date: Sep. 22, 2016

(30) Foreign Application Priority Data
Mar. 27, 2014 (DE) 20 2014 101 445.4
Jul. 3, 2014 (DE) 20 2014 103 047.6

(51) Int. Cl. F21K 9/62; H01L 27/15; F21V 7/00; H01L 33/50; F21S 4/20; F21V 5/04

(52) U.S. Cl. CPC F21K 9/62; F21S 4/20; F21V 5/04; F21V 7/0091; H01L 33/502; H01L 27/153

(57) ABSTRACT

The invention relates to a lighting device (1) for generating white light which has at least one strip of three light diodes (LEDs) (2) in a linear arrangement, wherein: a) each LED strip (2) has two outer LEDs (3) and one center LED (4); b) each of the two outer LEDs (3) and the center LED (4) are phosphor-converted white LEDs; and c) the distance of each of the color coordinates of the two outer LEDs to the color coordinates of the mixed light of the two outer LEDs and the center LED is smaller than the distance of the color coordinate of the center LED to the color coordinates of the mixed light of the two outer LEDs.

### FIELD OF THE INVENTION

The present invention is related to lighting devices for generating white light.

### BACKGROUND

Phosphor-converted diodes (LEDs) which emit white light, as are obtained during a production method, typically provide color temperatures and color coordinates that differ not only from batch to batch but also from LED to LED. This in turn necessitates classification of such LEDs after their production in respect of color temperatures and color coordinates, before such LEDs are used in a lighting device. Such classification typically makes it possible for a person skilled in the art to suitably select LEDs with a similar or identical classification, in order to ensure that homogeneous white light with a defined color temperature and color coordinate is emitted.

The classification of LEDs is typically carried out by using a binning method according to which the chromaticity and in particular the color coordinates and color temperatures of the LEDs of one or more production batches are determined and then classified according to a predetermined classification system. Normally, such predetermined classification systems consist of predefined regions, for example of bins and sub-bins, into which the LEDs are sorted according to their color temperature and color coordinate. One exemplary classification system is the ANSI bin curve (ANSI C78.377-2008). In the ANSI bin curve (ANSI C78.377-2008), bins and sub-bins are arranged in the region around the Planckian curve (black body curve) and typically comprise for example bins of 0, 1, 2, 3, 4, 5, 6, 7, 8, 9 etc., each bin being subdivided into sub-bins, for example bin 5 being further subdivided into sub-bins 5A, 5B, 5C, 5D, etc., and even further into sub-bins 5A1, 5A2, 5A3, 5A4, 5B1 5B2, 5B3, 5B4, 5C1, 5C2, 5C3, 5C4, 5D1, 5D2, 5D3, etc.

The selection of LEDs from such bins and sub-bins is typically according to the user preference on the basis of their color temperatures and color coordinates, in order to ensure homogeneous white light with few deviations in the color temperature and color coordinate. This, however, is a difficult task when it is necessary to consider both the cost efficiency and the color temperatures or color coordinates most suitable or desired for particular light emission, and to ensure a certain color tolerance in respect of different white light emissions.

Consequently, LEDs of different bins or sub-bins are typically combined with one another in order also to achieve a certain tolerance in the color temperature and the color coordinates. Large color tolerances, however, can be achieved only by selecting specifically selected bins or even individual bins for all the LEDs, which can make selection of suitable bins expensive. It is likewise possible to use crossed bins for all the LEDs, although this again makes the selection expensive and does not provide large color tolerances. Furthermore, it is then not possible to use a large number of bins from one production batch, which is a significant factor in terms of costs.

According to one possibility for overcoming this problem, the emitted light and also the color temperature and the color coordinate of LEDs of selected bins and sub-bins may be modulated in order to further adapt the color temperature and the color coordinate to those of the rest of the LEDs. This possibility has the advantage that it is possible to use different bins and sub-bins, which are not necessarily close to one another. As an example, cold white and warm white LEDs may be combined in a lighting element. Such a selection, however, typically requires that the active modulation of the light emission achieves the desired color temperature and color coordinate. The modulation of the white light generated may typically be carried out at the time of production of the LED or during the use of the LED.

One exemplary method for modulating white light is disclosed in EP 2 253 534 A2. The aforementioned application relates to a device and a method for tuning the color of an LED-based lamp to a desired color or color temperature. EP 2 253 534 A2 discloses inter alia a device which uses both “warm” and “cold” white LEDs, in which case the lamp may, for the purpose of providing a tunable lamp, comprise LEDs which belong to any desired number of “groups”, each group being defined as generating light within a different color range or color temperature range (or a “bin”). The regions which belong to these various groups preferably do not overlap, and the desired color or color temperature to which the lamp is tuned is somewhere between the colors or color temperatures which belong to the groups of LEDs. EP 2 253 534 A2 does not, however, provide any instruction of how such LEDs may advantageously be selected in order to achieve the object on which it is based. Instead, EP 2 253 534 A2 discloses that cold white LEDs and warm white LEDs, which are both always required, are individually operable so that different currents can be delivered to the various warm and cold white LEDs and the color temperature is further modulated to the desired values.

Another method for modulating white light, as disclosed in the art, is described in EP 2 378 840 A1. EP 2 378 840 A1 relates to a light-emitting device and to a method for controlling it, the light-emitting device comprising: a light source unit; a first and a second optical exciter which convert lights emitted by the light source unit into lights which have different color temperatures and different color coordinates to one another. The device also comprises a third optical exciter which emits light with a color coordinate and a color temperature, from which the lights converted by the second optical exciters differ. The device necessarily contains a sensor, which contains a first component signal, a second component signal and a third component signal, each of which respectively corresponds to light quantities of a first, a second and a third component of the light, which is emitted by the first, the second and the third optical exciters. The lighting device furthermore necessarily contains a controller for controlling the light quantity of the light source unit so that a color coordinate of the light emitted by the first optical exciter, by the second optical exciter and by the third optical exciter are arranged within a range which is formed by the color coordinates of the first, the second and the third optical exciter. The voltage changes of the power supply then modulate the light quantity of the light source unit under the control of the controller, so that the white light emission and the quantity can be correspondingly modulated in order to allow homogeneous light emission over a prolonged working time.

Methods such as that disclosed above are technically complicated and usually require active modulation of the light emission either before production of the lighting device or even over the entire lifetime of the lighting device. This necessitates significant energy input and does not allow cost-efficient production.

In view of the above, there is a need in the art to provide a simpler system which allows a person with knowledge of the art to provide a lighting device with a minimum amount of technical equipment, the production costs clearly being reduced and the risk of technical faults of the lighting device over its entire lifetime also being minimized. Notwithstanding, it is also an object of the present invention to allow the cost-efficient production of a lighting device with a color coordinate and a color temperature which are more homogeneous, preferably over a longer period of its lifetime or even its entire lifetime, and nevertheless to have the possibility of having LEDs from different bins and sub-bins.

### SUMMARY

The present invention relates to a lighting device (1) for generating white light, which comprises at least one strip (2) of three light-emitting diodes (LEDs) in a linear arrangement, wherein:
a) each LED strip (2) comprises two outer LEDs (3) and one central LED (4);
b) each of the two outer LEDs (3) and the central LED (4) are phosphor-converted white LEDs; and
c) the distance of each of the color coordinates of the two outer LEDs from the color coordinate of the mixed light of the two outer LEDs and of the central LED is less than the distance of the color coordinate of the central LED from the color coordinates of the mixed light of the two outer LEDs and of the central LED.

The present invention also describes a method for producing an LED device which emits white light, and the use of at least one strip which consists of three light-emitting diodes (LEDs) in a linear arrangement for generating white light.

### BRIEF DESCRIPTION OF THE FIGURES

The following figures are intended to represent in more detail the invention described above, and are not intended to restrict the scope of the patent claims thereto.

FIG. 1A: shows an exemplary lighting device (1) according to the invention which comprises at least one strip of three light-emitting diodes (LEDs) in a linear arrangement, each strip comprising two outer LEDs (3) and one central LED (4).

FIG. 1B: shows an exemplary cover (5) of the lighting device (1) according to the invention.

FIG. 1C: shows an exemplary lighting device (1) according to the invention in combination with an exemplary cover (5).

FIG. 2: shows a CIE chromaticity diagram with a black body curve (Planckian curve (black body curve) according to the 1931 CIE (Commission internationale de l'eclairage) color system.

FIG. 3: shows exemplary bins and sub-bins of the ANSI bin curve (ANSI C78.377-2008). The bins and sub-bins may, for example, be extended and subdivided in each direction according to the Cree classification system.

FIG. 4: shows exemplary bins and sub-bins of the ANSI bin curve (ANSI C78.377-2008), further bins and sub-bins being represented.

FIGS. 5 to 21: show in planes with the numbers 1 to 33 possible exemplary combinations of sub-bins according to the ANSI bin curve (ANSI C78.377-2008) according to the invention, which are preferably selected from combinations 2 to 33. The shown binning classes NA1 to ND4 generalize the sub-bins shown in FIGS. 3 and 4, N representing the respective number of the binning class, i.e. 0, 1, 2, 3, 4, 5, 6, 7, 8 or 9 of FIGS. 3 and 4.

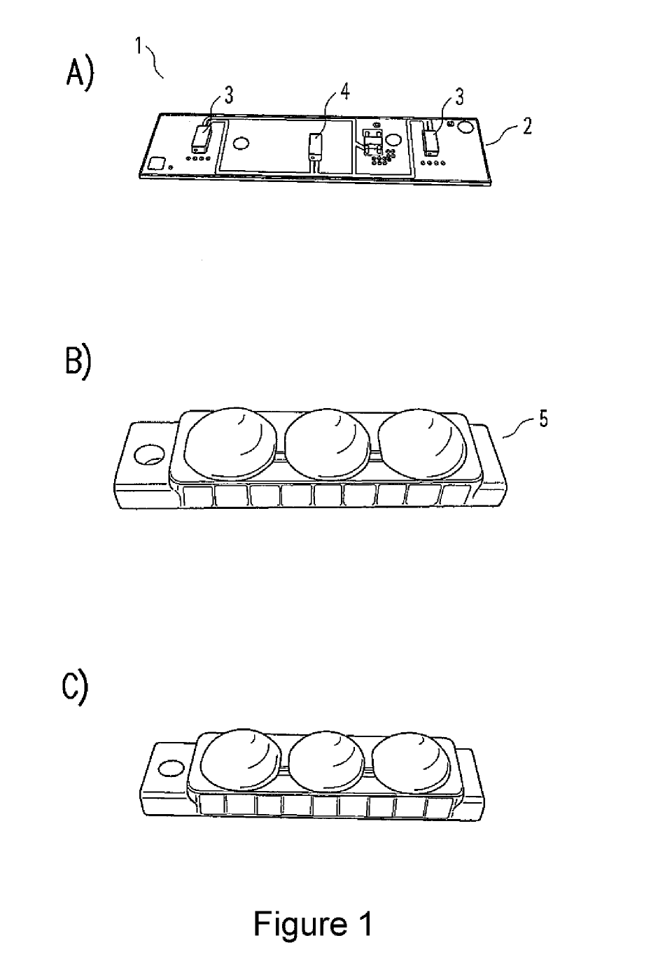

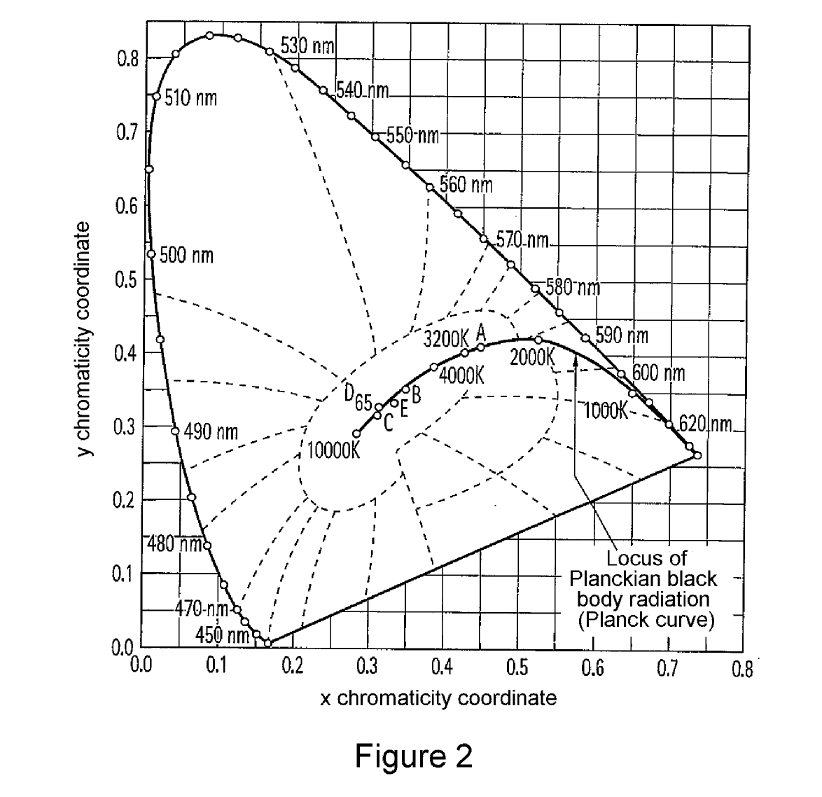

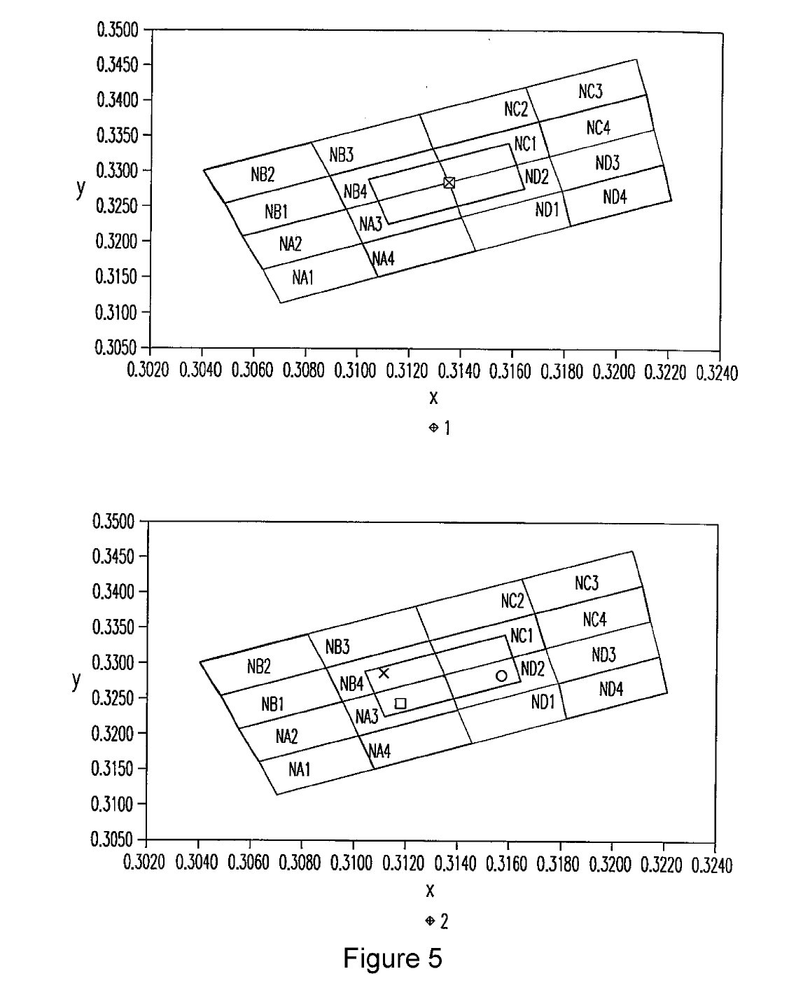

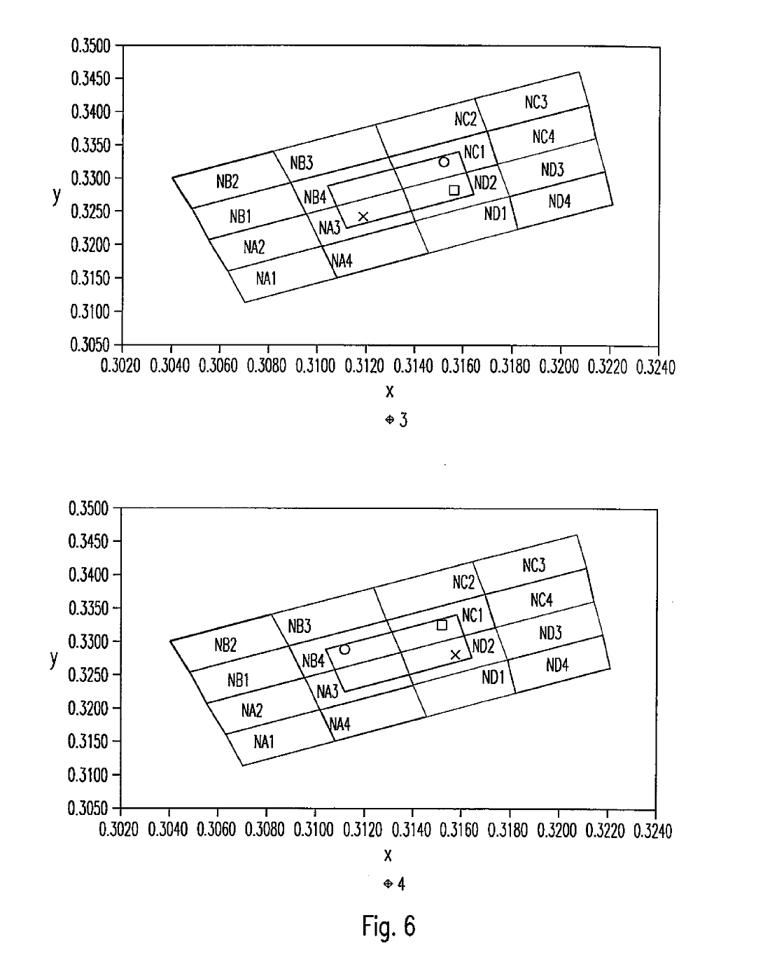

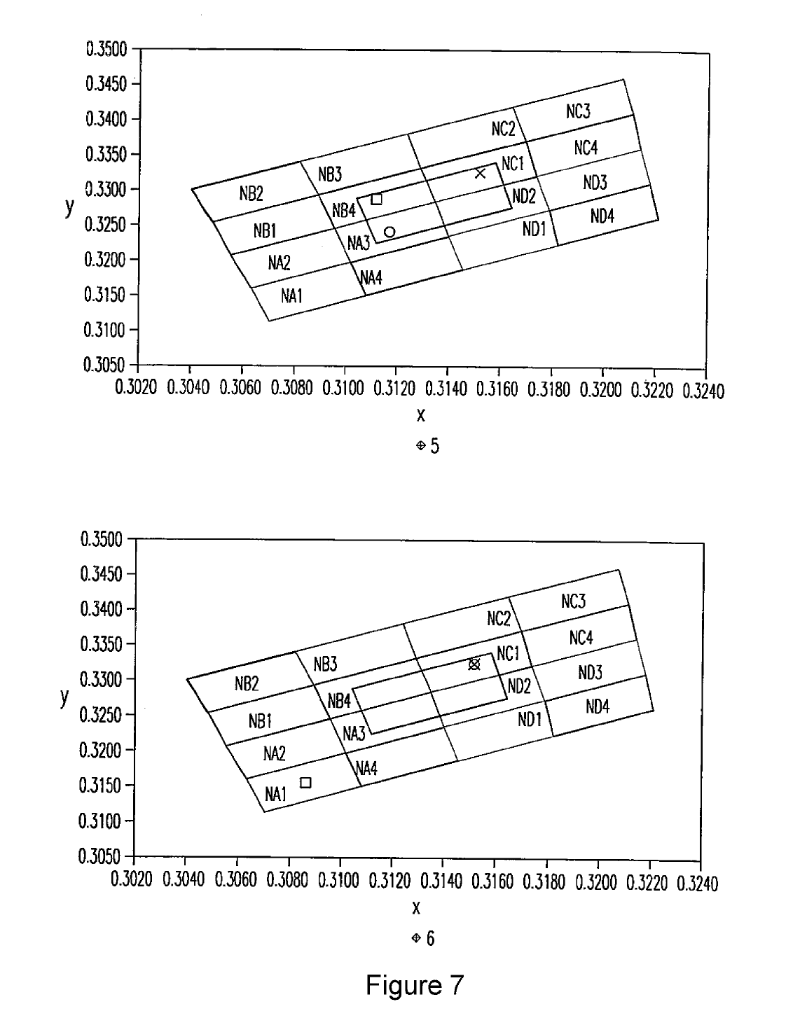

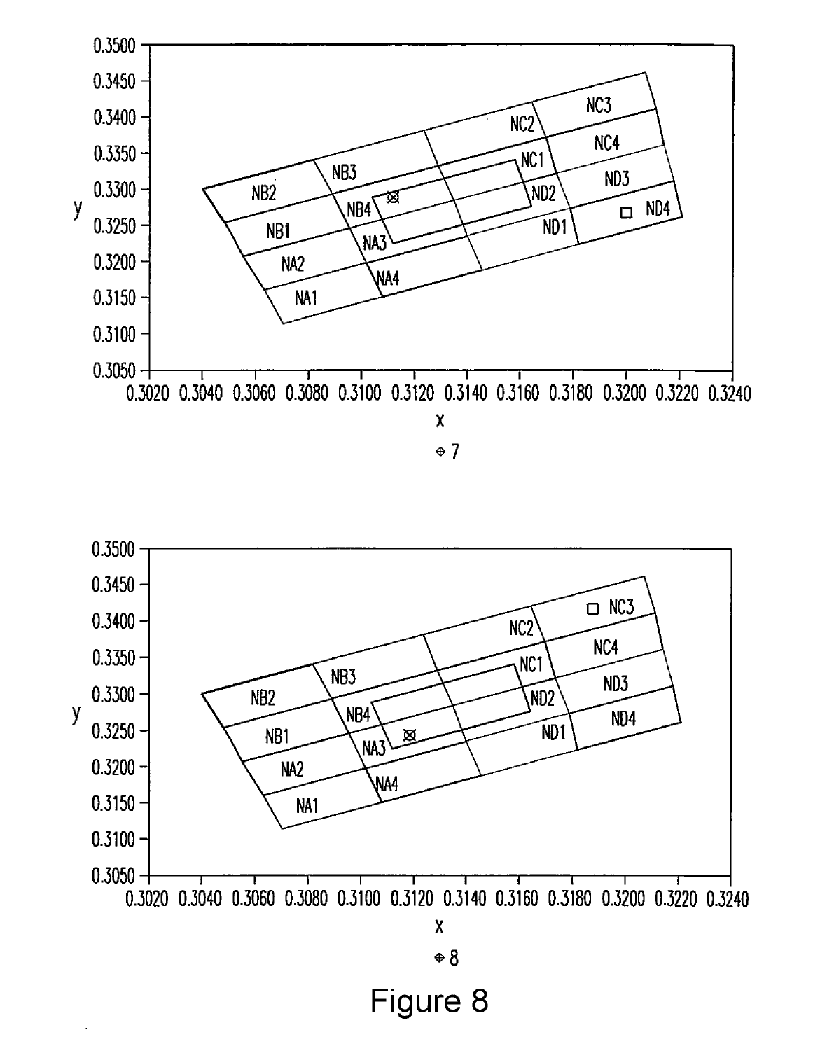

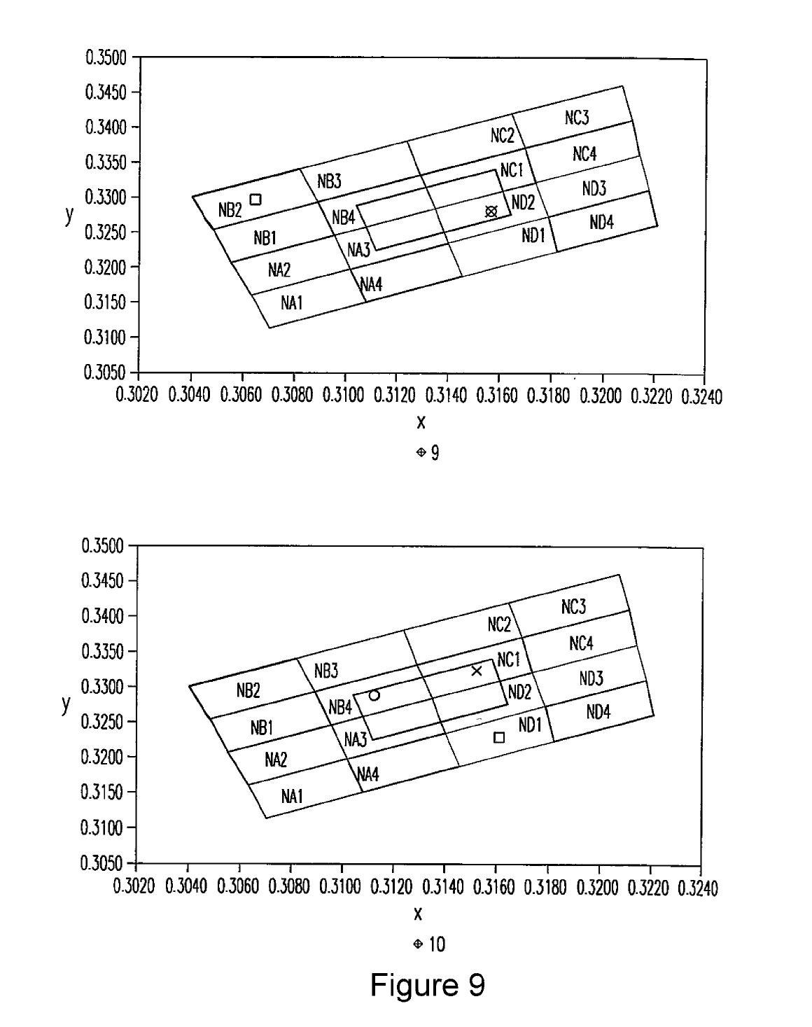

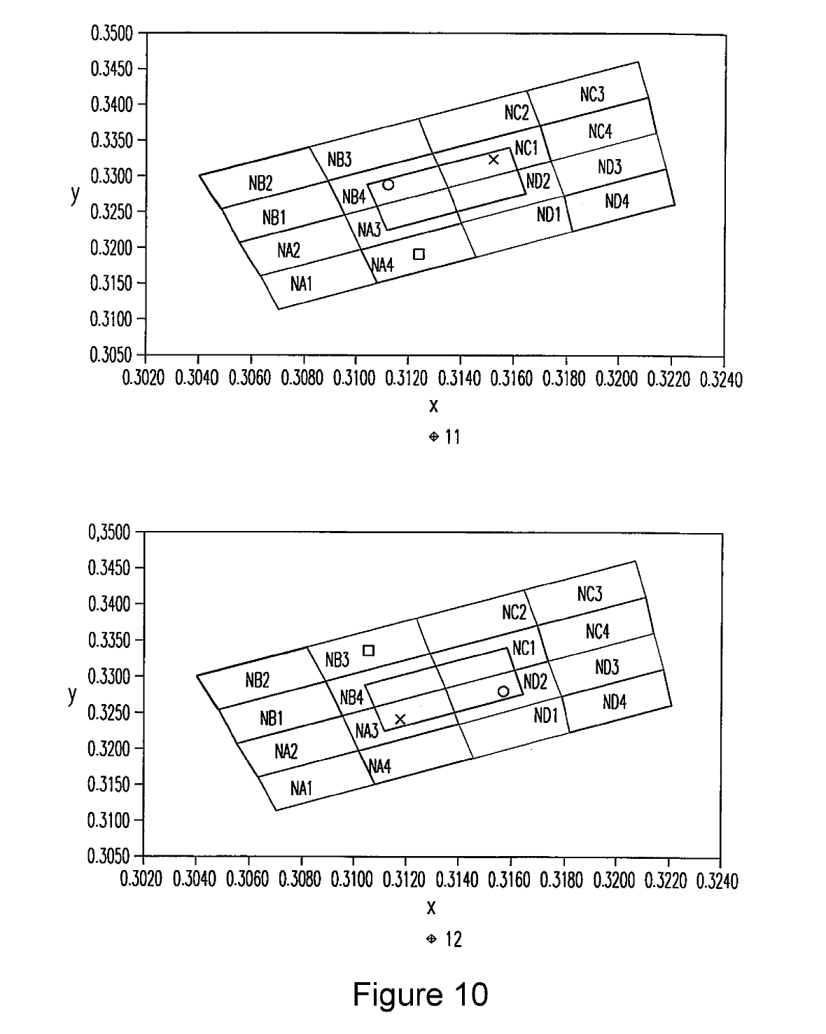

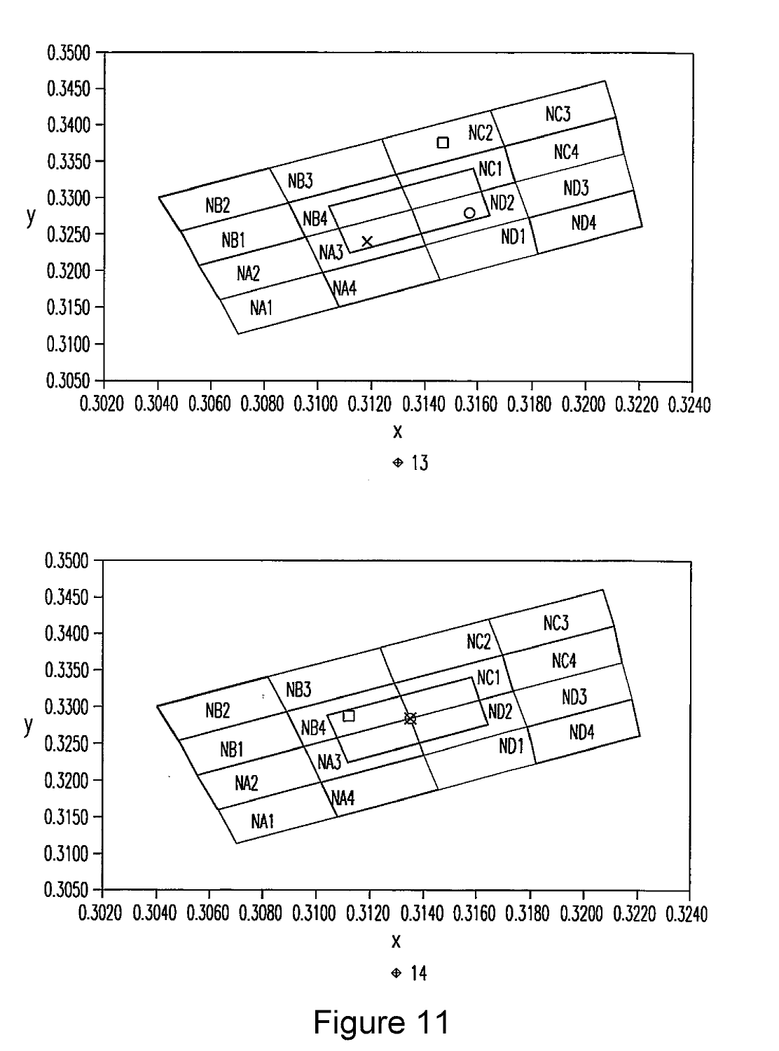

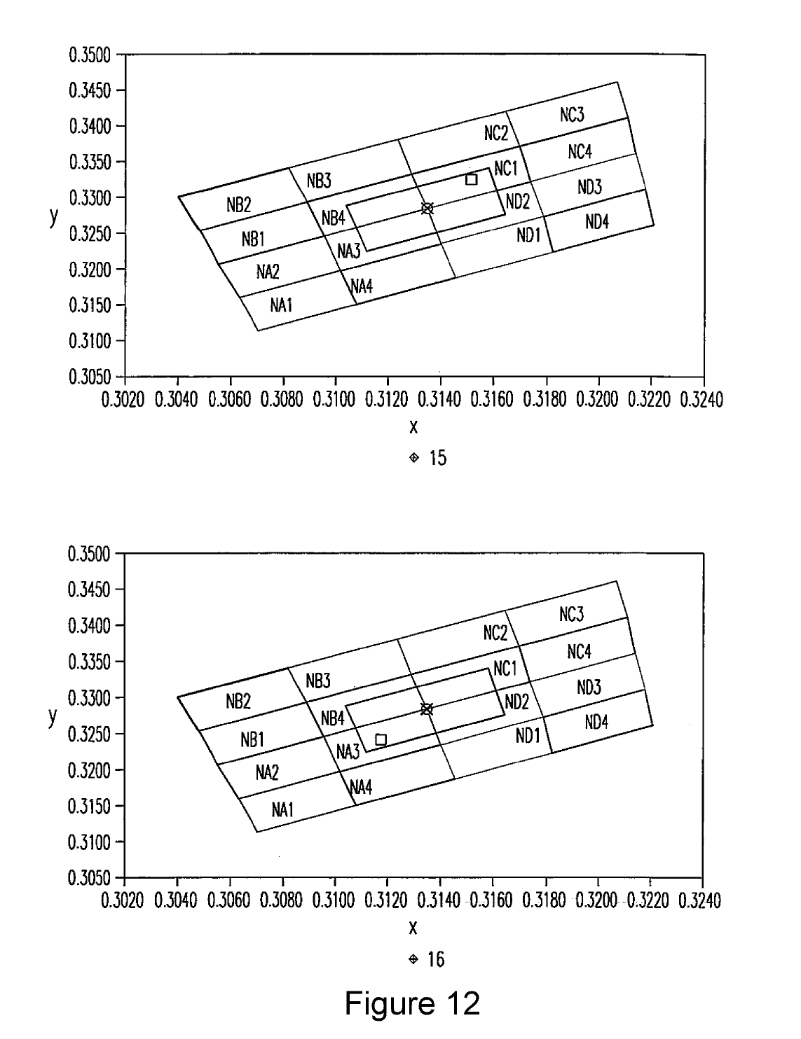

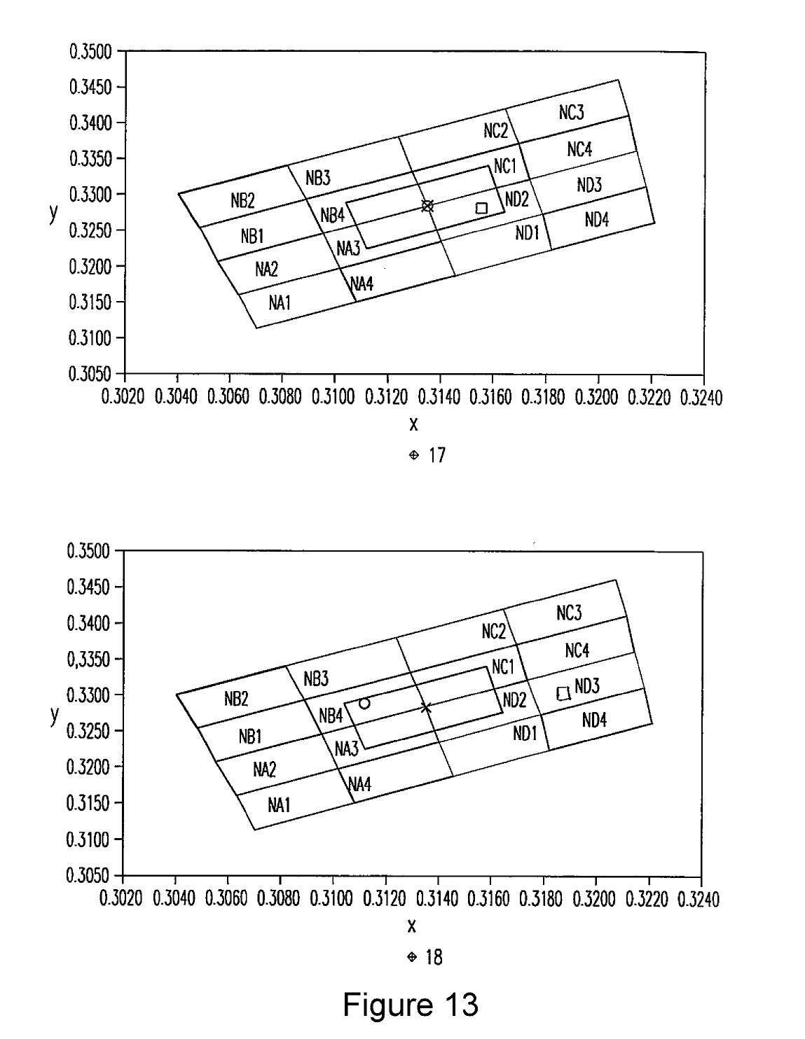

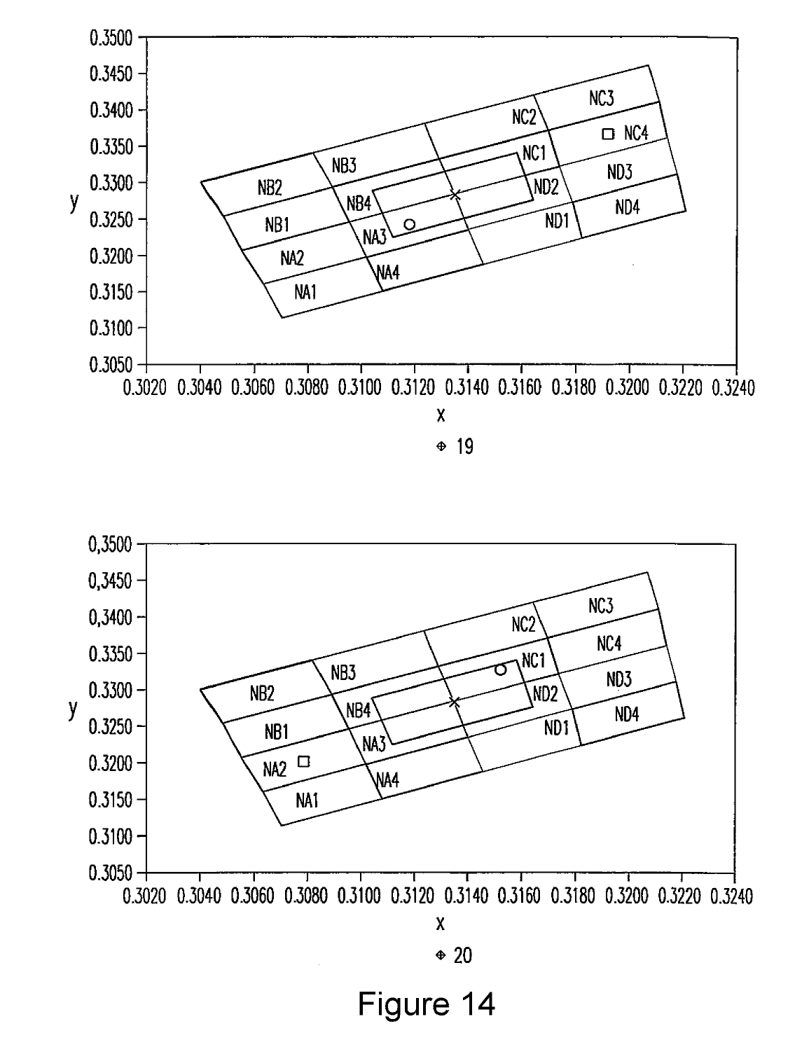

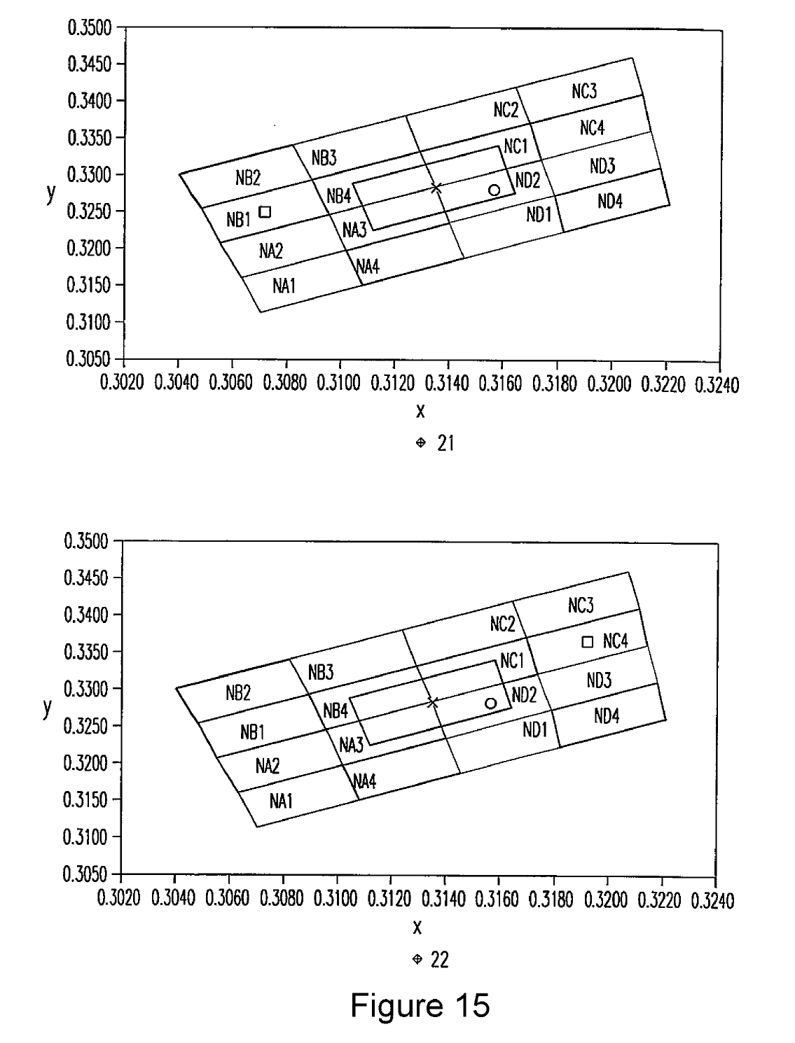

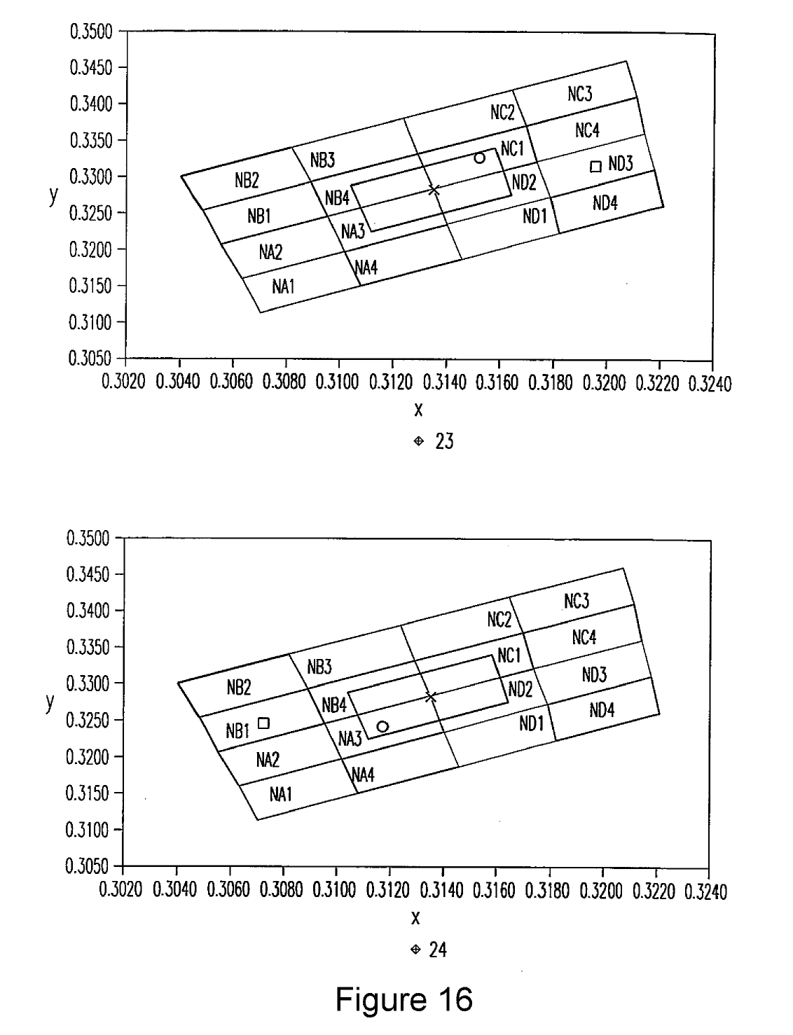

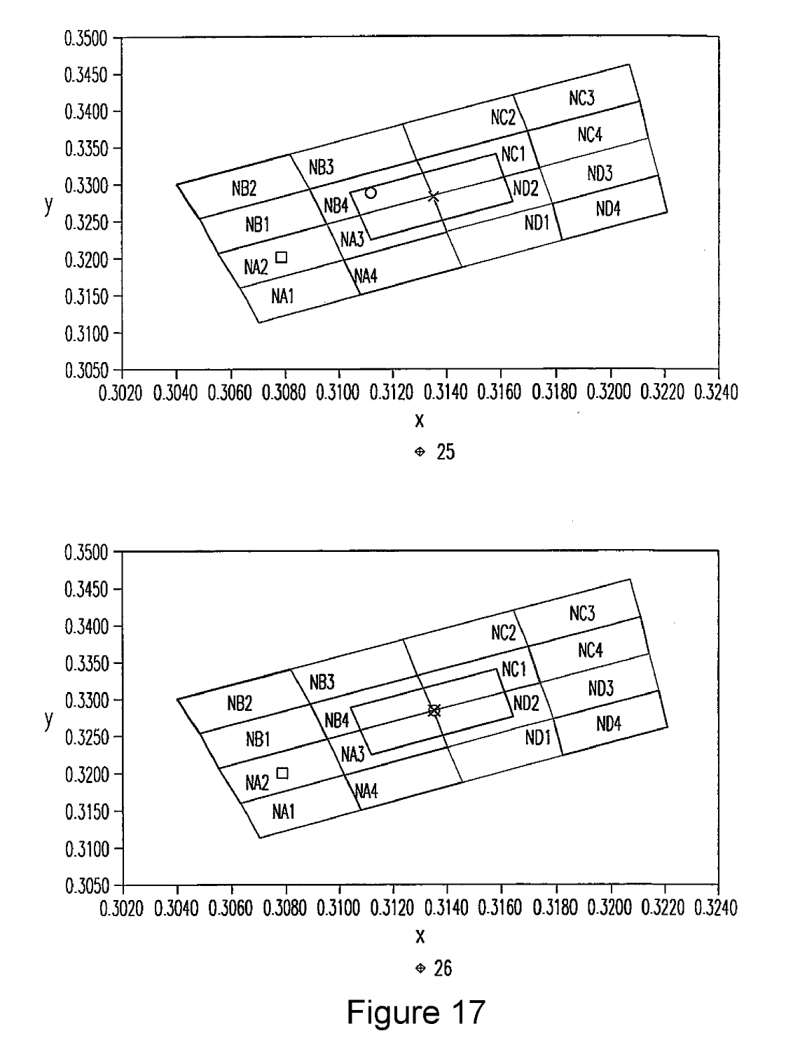

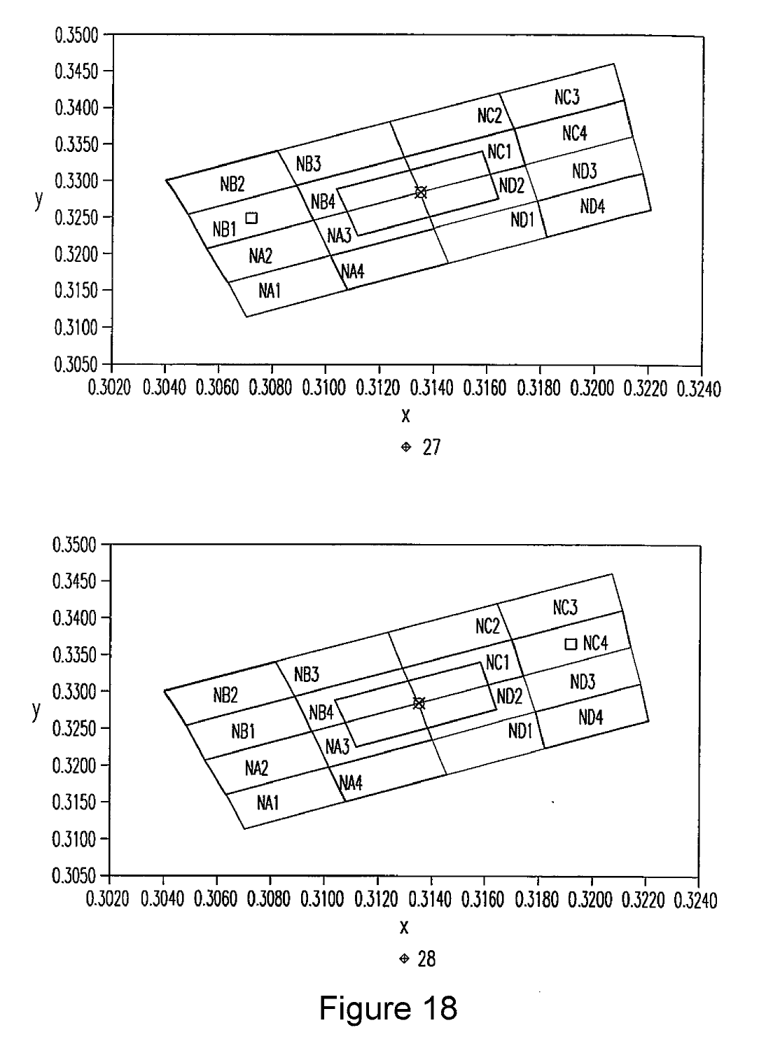

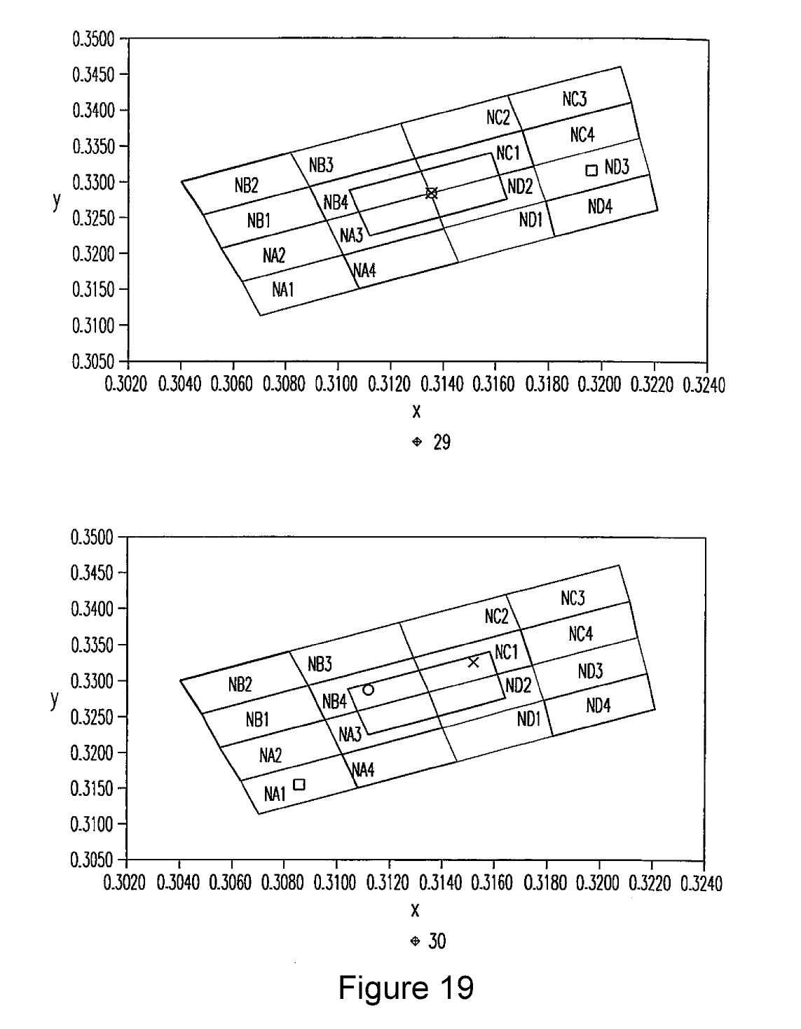

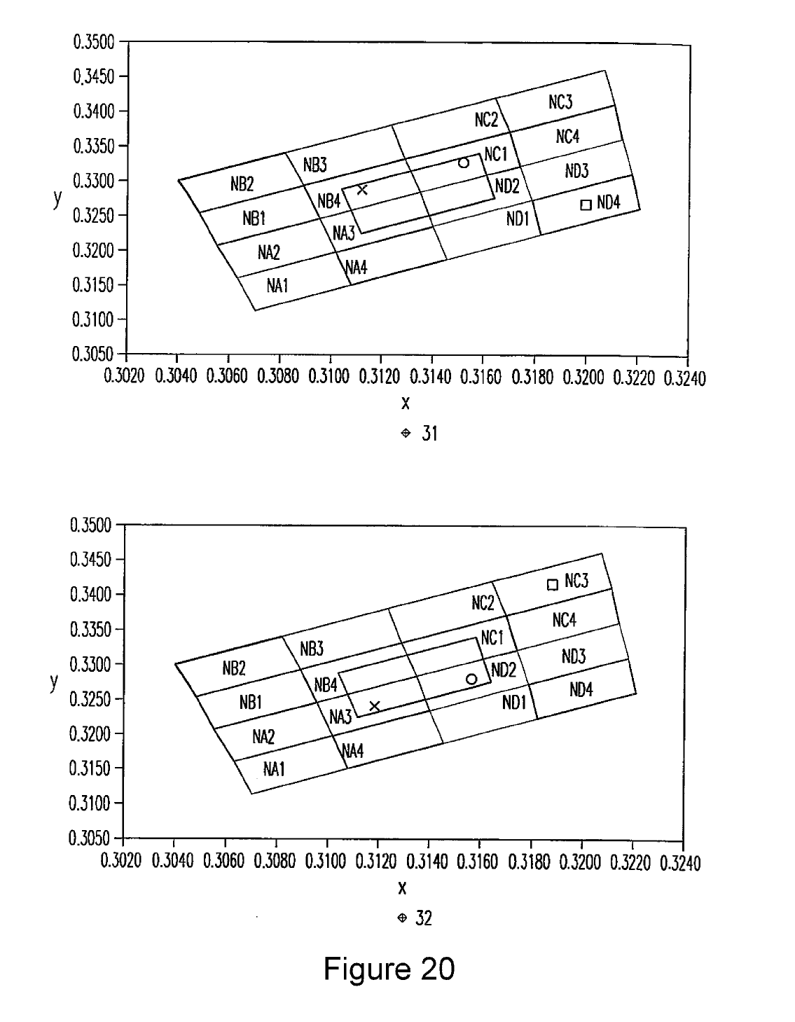

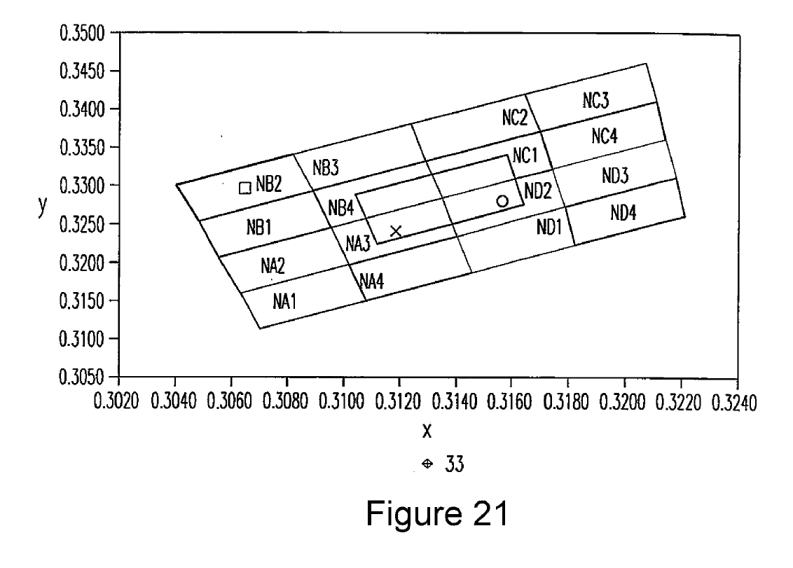

Each number 1 to 33 under the corresponding plane in FIGS. 5 to 21 relates to the numbers 1 to 33 in table 1. Symbols ×, □ and ∘ correlate with the same symbols in Table 1. The x and y values correspond to values in the chromaticity diagram, although the specific values are only shown by way of example.

### DETAILED DESCRIPTION OF THE PREFERRED EMBODIMENTS

The object on which the present invention is based is, according to a first embodiment, achieved by a lighting device (1) for generating white light, which comprises at least one strip (2) of three light-emitting diodes (LEDs) in a linear arrangement. In the lighting device (1) according to the invention:
a) each LED strip (2) preferably comprises two outer LEDs (3) and one central LED (4);
b) each of the two outer LEDs (3) and the central LED (4) are preferably phosphor-converted white LEDs.

Furthermore, the distance of each of the color coordinates of the two outer LEDs from the color coordinate of the mixed light of the two outer LEDs and of the central LED is less than the distance of the color coordinate of the central LED from the color coordinates of the mixed light of the two outer LEDs and of the central LED.

In the context of the present invention, the lighting device (1) comprises at least one LED strip (2), the LED strip (2) preferably comprising or consisting of three light-emitting diodes (LEDs) in a linear arrangement. Each LED strip (2) therefore typically contains two outer LEDs (3) and one central LED (4). The LED strips (2) can typically be separated from one another. These LED strips (2) and/or the lighting device (1) according to the invention may according to requirements (a) be arranged on one or more light chains, but optionally also on one or more regions or on one or more three-dimensional arrangements.

Preferably, the lighting device (1) according to the invention emits white light, the white light typically being mixed light which consists of the white light emissions of each of the LEDs of the at least one LED strip (2). Preferably, the white color of the lighting device (1) is obtained by mixing the light of the two outer LEDs (3) and of the central LED (4) of each LED strip (2).

Even more preferably, the white (mixed) light which is emitted by the lighting device (1) according to the invention is white light with a color temperature that is selected from a warm white color, a cold white color or a color between a warm white color and a cold white color.

Preferably, the white light which is emitted by the lighting device (1) is white mixed light, more preferably with a color coordinate which lies on or in the vicinity of the Planckian curve (black body curve), a white color coordinate which lies inside a MacAdam ellipse, a white color coordinate which lies on or in the vicinity of the ANSI bin curve (ANSI C78.377-2008) or in a bin or preferably a sub-bin thereof, or a white color coordinate according to the 1931 CIE (Commission internationale de l'eclairage) color system.

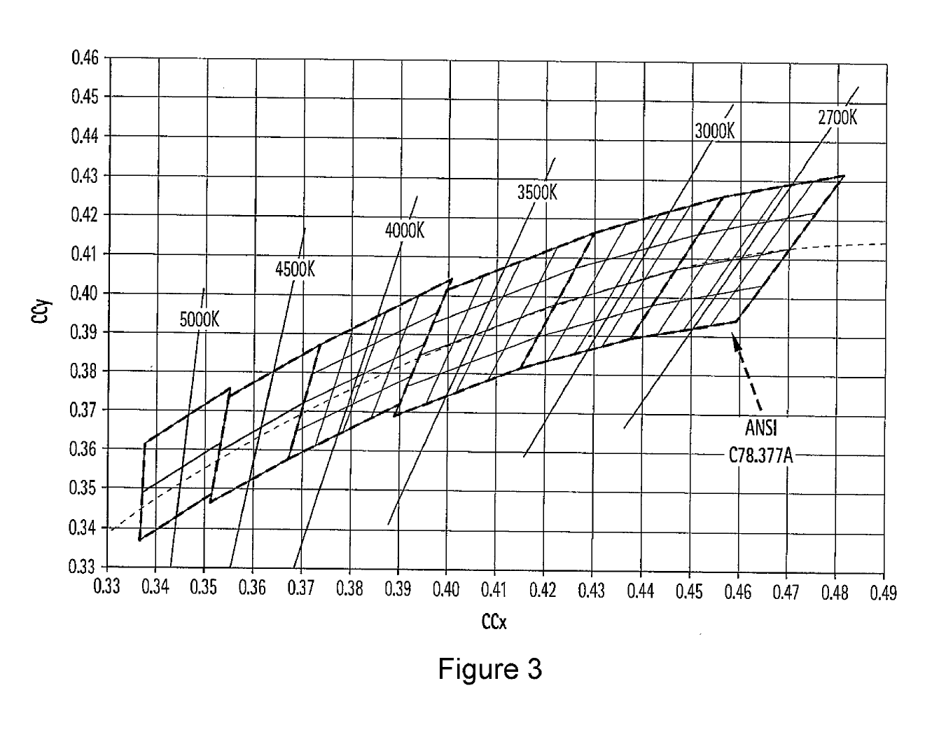

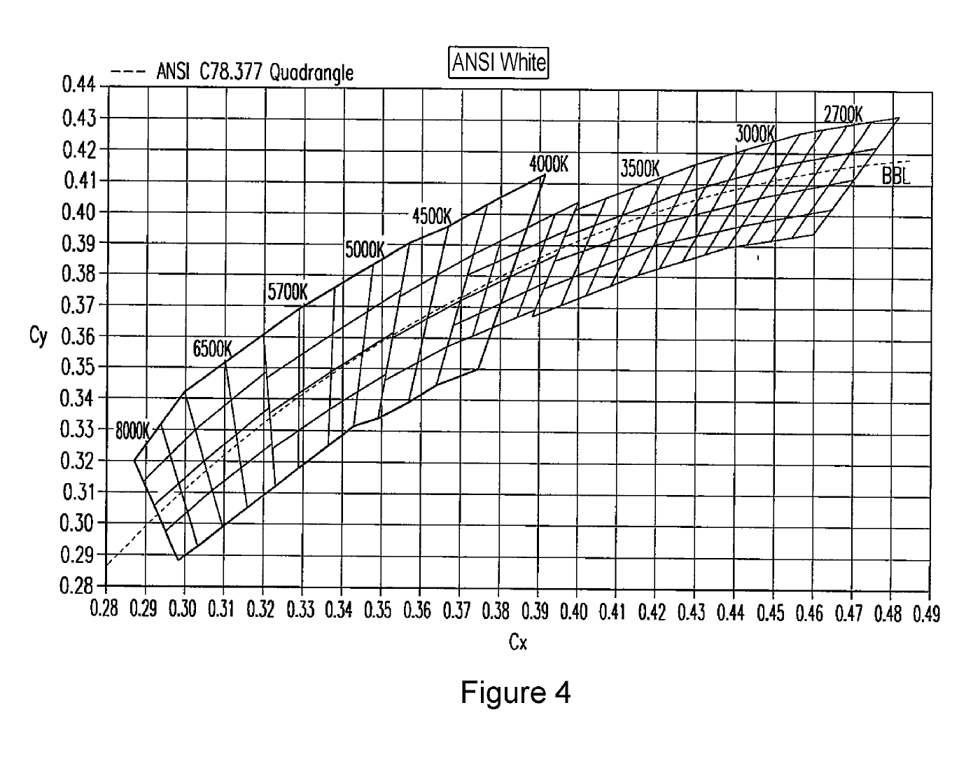

In general, color coordinates in the context of the present invention are determined on the basis of the ANSI bin curve (ANSI C78.377-2008), a bin or preferably a sub-bin thereof, and/or based on the 1931 CIE (Commission internationale de l'eclairage) color system. Bins and sub-bins which are suitable according to the present invention are shown, for example, in FIGS. 3 and 4 and in Table 1, and they preferably follow the system of the ANSI bin curve (ANSI C78.377-2008).

In the context of the present invention, the Planckian curve (blackbody curve), the MacAdam ellipse, the ANSI bin curve (ANSI C78.377-2008), a bin or preferably a sub-bin thereof, or the 1931 CIE (Commission internationale de l'eclairage) color system are well known to the person skilled in the art. Bins or sub-bins of such definitions may be further subdivided or extended, for example by the further definition of bins or sub-bins of the ANSI bin curve (ANSI C78.377-2008), such as have been developed by the Cree Incorporation, US (“Cree bins and sub-bins”). Such bins and sub-bins, as developed by the Cree Incorporation, are also included in the definition of bins and sub-bins of the present invention.

According to one aspect of the present invention, the white light which is emitted by each of the two outer LEDs (3) and by the central LED (4) of the LED strip (2) of the lighting device (1) according to the invention may, again independently of one another, have a color temperature selected between warm white light and cold white light, preferably a color temperature which is selected from warm white light or cold white light, and/or a color temperature between warm white light and cold white light, for example neutral white light.

In this context, preferably each of the individual LEDs of the LED strip (2) of the lighting device (1) according to the invention may independently of one another be selected from LEDs which emit white light and have a color coordinate which lies on or in the vicinity of the Planckian curve (black body curve), a white color coordinate which lies inside a MacAdam ellipse, a white color coordinate which lies on or in the vicinity of the ANSI bin curve (ANSI 078.377-2008) or in a bin or preferably a sub-bin thereof, and/or a white color coordinate according to the 1931 CIE (Commission internationale de l'eclairage) color system.

Preferably, the white light of each of the two outer LEDs (3) and of the central LED (4) of the LED strip (2) of the lighting device (1) according to the invention is selected from white light with a color temperature in the range of from about 1500 K to about 8000 K, more preferably a color temperature in the range of from about 2700 K to about 6500 K.

In the context of the present invention, the color temperature of warm white light preferably lies in the range of from about 1500 K to about 300 K, or preferably in the range of from about 2700 K to about 3000 K. The color temperature of cold white light preferably lies in the range of from about 4000 K to about 8000 K, more preferably in the range of from about 4000 K to about 6500 K. The color temperature may also be selected from each central range between cold and warm white light, as formed by one of the aforementioned values, or from a range which is typically referred to as “neutral white light”, preferably in the range of from about 3500 K to about 4500 K.

According to one aspect, the color coordinate of a first outer LED (3) of each LED strip (2) of the lighting device (1) according to the invention is selected from a white color coordinate, as defined above, which lies in a bin or preferably sub-bin of the ANSI bin curve (ANSI C78.377-2008), preferably a Cree bin or sub-bin thereof. Furthermore, the color coordinate of the second outer LED (3) of the same LED strip (2) may be selected from a white color coordinate, as defined above, which lies in a bin or preferably sub-bin of the ANSI bin curve (ANSI 078.377-2008), as defined above, or preferably a Cree bin thereof, the bin or sub-bin either neighboring the bin or sub-bin of the color coordinate of the first outer LED (3) or identical to the bin or sub-bin of the color coordinate of the first outer LED (3). In the present inventive context, “neighboring” may include directly neighboring sub-bins (no sub-bin between them) or bins or sub-bins which are separated by one or more bins or sub-bins.

In the lighting device (1) according to the invention the distance of each of the color coordinates of the two outer LEDs from the color coordinate of the mixed light of the two outer LEDs and of the central LED is less than the distance of the color coordinate of the central LED from the color coordinates of the mixed light of the two outer LEDs and of the central LED. The color coordinate of the mixed light of the two outer LEDs and of the central LED may also be referred to as a “middle”. Here, the color coordinates of the two outer LEDs are in greater proximity to one another than the color coordinate of the first outer LED is to the color coordinate of the central LED, or the color coordinate of the second outer LED is to the color coordinate of the central LED.

For the purpose of the present invention, the distance of each of the color coordinates of the LEDs of each LED strip (2) is calculated on the basis of the color coordinate of the mixed light which is generated by all three white light-emitting LEDs of the LED strip (2). The mixed light has in this case a color coordinate which is defined as the “middle” of a triangular surface which is defined by the color coordinates of the two outer LEDs (3) and of the central LED (4). This applies, in particular, when the color coordinates of the two outer LEDs (3) are different to one another. The “middle” may be calculated on the basis of the average values of the x and y coordinates of all three color coordinates.

If the color coordinates of the two outer LEDs (3) are identical to one another, the color coordinate of the mixed light of the LED light strip (2) (“middle”) is calculated similarly on the basis of the color coordinates of the two outer LEDs (3) and of the central LED (4). The color coordinate of the mixed light is then typically on a straight line between the color coordinates of the two outer LEDs (3) and of the central LED (4).

Consequently, the color coordinates of the two outer LEDs (3) may, according to one aspect, be either identical to one another or different to one another.

In each of these two cases, the determination of the color coordinates of the mixed light of the two outer LEDs and of the central LED (“middle”) may be carried out by calculating the average x and y coordinates of each of these LEDs as follows:

xmiddle=(x1+x2+x3)/3; and

ymiddle=(y1+y2+y3)/3.

Here, x1+x2+x3 preferably represents the sum of the X coordinates of the two outer (x1, x3) and of the central (x2) LEDs, and y1+y2+y3 preferably represents the sum of the Y coordinates of the two outer (y1, y3) and of the central (y2) LEDs. xmiddle and ymiddle represent the central x and y coordinates, the combination which defines the “middle”, i.e. the color coordinate of the mixed light of the two outer LEDs and of the central LED.

If the color coordinates of the two outer LEDs are identical to one another, the color coordinates of the two outer LEDs (3) and of the central LED (4) are preferably selected from bins and sub-bins of the ANSI bin curve (ANSI C78.377-2008), as defined above, preferably from sub-bins of the ANSI bin curve.

Even more preferably, in the case that the color coordinates of the two outer LEDs (3) are identical to one another, the color coordinates of the two outer LEDs (3) are selected according to the ANSI bin curve (ANSI C78.377-2008), as defined above, from a bin or cross-bin, and the color coordinate of the central LED (4) is selected from a bin or preferably sub-bin, which is either identical to the bin or preferably the sub-bin of the two outer LEDs (3) or is different to the bin or preferably the sub-bin of the two outer LEDs (3). In the latter case, the color coordinate of the central LED (3) is preferably selected from a bin, or preferably a sub-bin, which according to the ANSI bin curve (ANSI C78.377-2008) of the two outer LEDs (3) neighbors the bin or preferably the sub-bin. Preferably, sub-bins are used.

Even more preferably, in the case that the color coordinates of the two outer LEDs (3) are identical to one another, the color coordinate of the central LED (4) is selected from a bin or preferably sub-bin which is separated from the bin or preferably the sub-bin of the outer LEDs (3) according to the ANSI bin curve (ANSI C78.377-2008), as defined above, by no more than from 1 to 4 bins or sub-bins, more preferably according to the ANSI bin curve (ANSI C78.377-2008), as defined above, by no more than one or two sub-bins, and most preferably according to the ANSI bin curve (ANSI C78.377-2008), as defined above, by no more than one bin or preferably one sub-bin. Particularly preferably, the color coordinate of the central LED (4) is preferably selected from a bin or sub-bin which directly neighbors the bin or sub-bin of the outer LEDs (3). Likewise, the color coordinate of the central LED (4) may be in the same sub-bin as the outer LEDs (3). Preferably, sub-bins are used.

In the alternative case, that the color coordinates of the two outer LEDs (3) are not identical to one another, the color coordinates of the two outer LEDs (3) are preferably selected in such a way that the distance of each of the color coordinates of the two outer LEDs (4) from the color coordinate of the mixed light of the two outer LEDs and of the central LED is less than the distance of the color coordinates of the central LED from the color coordinates of the mixed light of the two outer LEDs and of the central LED. Preferably, sub-bins are used.

In this alternative case, in which the color coordinates of the two outer LEDs (3) are not identical to one another, the color coordinates of each of the two outer LEDs (3) of the lighting device (1) according to the invention are preferably selected independently of one another from a white color coordinate, as defined above, which lies in a bin or sub-bin of the ANSI bin curve (ANSI C78.377-2008), as defined above, preferably a Cree bin or sub-bin. Preferably, sub-bins are used.

If, furthermore, the color coordinates of the two outer LEDs (3) are not identical to one another, the bin or the sub-bin of the color coordinate of the first outer LED (3) is preferably selected in such a way that it neighbors the bin or sub-bin of the color coordinate of the second outer LED (3) or is in the same sub-bin. The selection of the (neighboring) bin or preferably sub-bin of the color coordinate of the second outer LED (3) is preferably carried out in such a way that a bin, or preferably sub-bin, is selected which is near or even in closest proximity to the bin or preferably sub-bin of the color coordinate of the first outer LED (3). Preferably, the selected bins or sub-bins for the first and second outer LEDs (3) according to the ANSI bin curve (ANSI C78.377-2008), as defined above, may be separated by no more than one or two sub-bins and most preferably according to the ANSI bin curve (ANSI C78.377-2008), as defined above, may be separated by no more than one sub-bin or may be in the same sub-bin. Particularly preferably, the color coordinates, or the selected bins or sub-bins, for the first and second outer LEDs (3) directly neighbor one another or are selected according to the ANSI bin curve (ANSI C78.377-2008), as defined above, from the same sub-bin. Preferably, sub-bins are used.

According to one exemplary aspect of the alternative case, in which the color coordinates of the two outer LEDs (3) are not identical to one another, a bin or sub-bin may be arranged above the Planckian curve (blackbody curve), and the corresponding or directly neighboring cross-bin may be arranged below the Planckian curve (blackbody curve). Preferably, sub-bins are used.

Lastly, for the case in which the color coordinates of the two outer LEDs (3) are not identical to one another, the color coordinate of the central LED (4) is selected from a bin or preferably sub-bin which according to the ANSI bin curve (ANSI C78.377-2008), as defined above, or a corresponding Cree cross-bin or cross-sub-bin of the bin or preferably sub-bin of at least one of the outer LEDs (3) is separated by no more than from 1 to 4 bins or sub-bins, preferably by no more than from 1 to 3 sub-bins or from 2 to 3 sub-bins, more preferably by no more than 1 or 2 sub-bins and most preferably by 1 or 2 bins or preferably sub-bins, or the color coordinate of the central LED (4) may be in the same sub-bin as at least one of the outer LEDs (3).

According to one exemplary aspect of the present invention, suitable cross-bins or cross-sub-bins may be selected from combinations of bins or sub-bins of the ANSI bin curve (ANSI C78.377-2008), as defined below.

In the case in which the color coordinates of the two outer LEDs (3) are identical to one another, the color coordinates of the two outer LEDs (3) (identically) and the color coordinate of the central LED (4) may, for example, be selected from the same bin or sub-bin or from combinations of bins NA and NC or NB and ND, N in each of the cases defined above representing the number of the bin, for example 0, 1, 2, 3, 4, 5, 6, 7, 8 or 9 etc. in the ANSI bin curve system (ANSI C78.377-2008), or as extended for example by the Cree bin system (Cree Inc., US). Cross-bins may also be selected from combinations of bins or sub-bins NA and NB or NC and ND, or from combinations of bins ND and (N+1)B or NC and (N+1)A, etc., without being restricted thereto.

Preferably, the color coordinates of the two outer LEDs (3) (identically) and the color coordinate of the central LED (4) may, for example, be selected from combinations of sub-bins NB4 and ND2, NC1 and NA3, but also from combinations of sub-bins NB1 and NA2, NB4 and NA3, NC1 and ND2, NC4 and ND3, NB1 and NB4, NB4 and NC1, NC1 and NC4, NA2 and NA3, NA3 and ND2, ND2 and ND3, NC4 and (N+1)B1, ND3 and (N+1)A2 etc. according to the ANSI bin curve (ANSI C78.377-2008), without being restricted thereto. Again, N represents the number of the bin, for example 0, 1, 2, 3, 4, 5, 6, 7, 8 or 9 etc. in the ANSI bin curve system.

In the case that the color coordinates of the two outer LEDs (3) are not identical to one another, the color coordinates of the two outer LEDs (3) are selected independently according to the ANSI bin curve (ANSI C78.377-2008) either from the same bin or sub-bin or from different bins or sub-bins thereof. In the latter case, the selection of combinations of suitable bins or sub-bins according to the ANSI bin curve (ANSI C78.377-2008) is carried out for the first and for the second outer LED (3) as described above in the first alternative of identical color coordinates of the outer LEDs (3).

Furthermore, in the alternative case that the color coordinates of the two outer LEDs (3) are not identical to one another, the color coordinate of the central LED (4) is selected from a bin, or preferably a sub-bin, which is separated from the bin or preferably the sub-bin of at least one of the outer LEDs (3), as defined above, by no more than from 1 to 4 bins or sub-bins, from 2 to 3 bins or sub-bins, or 1 or 2 bins or sub-bins.

According to one particularly preferred aspect, suitable bins or sub-bins for both the two alternatives explained above are selected from the following combinations of sub-bins according to the ANSI bin curve (ANSI C78.377-2008), preferably from combinations 2 to 33:

TABLE 1
Shows possible combinations of sub-bins according to the ANSI bin
curve (ANSI C78.377-2008) according to the invention, which are
preferably selected from combinations 2 to 33. The combinations 1
to 33 shown correspond to FIGS. 5 to 21, each number in Table 1
being referred to in the corresponding figure of FIGS. 5 to 21.

| | 1^{st} Outer LED (3) | Central LED (4) | 2^{nd} Outer LED (3) |
|---|---|---|---|
| No. | x | □ | ∘ |
| 1 | NA3/NB4/NC1 | Same as for 1^{st} | Same as for 1^{st} |
| | or ND2 | outer LED | outer LED |
| 2 | NB4 | NA3 | ND2 |
| 3 | NA3 | ND2 | NC1 |
| 4 | ND2 | NC1 | NB4 |
| 5 | NC1 | NB4 | NA3 |
| 6 | NC1 | NA1 | NC1 |
| 7 | NB4 | ND4 | NB4 |
| 8 | NA3 | NC3 | NA3 |
| 9 | ND2 | NB2 | ND2 |
| 10 | NC1 | ND1 | NB4 |
| 11 | NC1 | NA4 | NB4 |
| 12 | NA3 | NB3 | ND2 |
| 13 | NA3 | NC2 | ND2 |
| 14 | NA3/NB4/NC1 | NB4 | Same as for 1^{st} |
| | or ND2 | | outer LED |
| 15 | NA3/NB4/NC1 | NC1 | Same as for 1^{st} |
| | or ND2 | | outer LED |
| 16 | NA3/NB4/NC1 | NA3 | Same as for 1^{st} |
| | or ND2 | | outer LED |
| 17 | NA3/NB4/NC1 | ND2 | Same as for 1^{st} |
| | or ND2 | | outer LED |
| 18 | NA3/NB4/NC1 | ND3 | NB4 |
| | or ND2 | | |
| 19 | NA3/NB4/NC1 | NC4 | NA3 |
| | or ND2 | | |
| 20 | NA3/NB4/NC1 | NA2 | NC1 |
| | or ND2 | | |
| 21 | NA3/NB4/NC1 | NB1 | ND2 |
| | or ND2 | | |
| 22 | NA3/NB4/NC1 | NC4 | ND2 |
| | or ND2 | | |
| 23 | NA3/NB4/NC1 | ND3 | NC1 |
| | or ND2 | | |
| 24 | NA3/NB4/NC1 | NB1 | NA3 |
| | or ND2 | | |
| 25 | NA3/NB4/NC1 | NA2 | NB4 |
| | or ND2 | | |
| 26 | NA3/NB4/NC1 | NA2 | Same as for 1^{st} |
| | or ND2 | | outer LED |
| 27 | NA3/NB4/NC1 | NB1 | Same as for 1^{st} |
| | or ND2 | | outer LED |
| 28 | NA3/NB4/NC1 | NC4 | Same as for 1^{st} |
| | or ND2 | | outer LED |
| 29 | NA3/NB4/NC1 | ND3 | Same as for 1^{st} |
| | or ND2 | | outer LED |
| 30 | NC1 | NA1 | NB4 |
| 31 | NB4 | ND4 | NC1 |
| 32 | NA3 | NC3 | ND2 |
| 33 | NA3 | NB2 | ND2 |

The symbols x, □ and ∘ correlate with the symbols in FIGS. 5 to 21. The expression “NA3/NB3/NC1 or ND2” preferably means “middle of the bins NA3/NB4/NC1 and ND2”.

In another aspect of the lighting device (1) as defined here, the white light of the lighting device (1) is obtained by mixing the light of the two outer LEDs (3).

Preferably, according to one aspect, the lighting device (1) according to the invention comprises a plurality of strips of three phosphor-converted white light-emitting diodes (LED), each LED strip (2) consisting of two outer LEDs (3) and one central LED (4), the number of LED strips (2) preferably lying in a range of between 2 and 10000, for example between 2 and 5000, 2 and 1000, most preferably in a range of between 2 and 700, even more preferably in a range of between 2 and 500. Particularly preferably, the LED strips (2) are arranged in a linear form as an LED chain or in a two-dimensional or three-dimensional arrangement.

In the lighting device (1) according to the present invention, each LED strip (2) may have a cover (5), which preferably comprises a lens for each of the two outer LEDs (3) and the central LED (4). Such a cover and/or the lens may be formed from any suitable material, for example polyethylene or polypropylene, epoxy resin, optionally a silicone coating, etc.

Likewise, preferably as an alternative to the aforementioned cover, each LED strip (2) in the lighting device (1) according to the invention has a total internal reflection (TIR) lens. Such a total internal reflection (TIR) lens may be formed from any suitable material, for example polyethylene or polypropylene, epoxy resin, a silicone coating, etc., preferably as defined above for the cover.

In the lighting device (1) according to the present invention, the LED strips (2) may preferably be connected, preferably by means of series connection, in the form of a chain of LED strips (2).

The LEDs of the lighting device (1) according to the invention, in particular the LEDs of each LED strip (2), as defined here, are typically selected independently of one another from any suitable LEDs. Preferably, each of the two outer LEDs (3) and the central LED (4) of each LED strip (2) are selected independently of one another from LEDs which comprise a blue LED and at least one phosphor, the phosphor preferably being selected from the group which comprises or consists of garnets that are doped with rare earths, including YAG, thiogallates that are doped with rare earths, aluminates that are doped with rare earths, orthosilicates that are doped with rare earths and/or oxyorthosilicates that are doped with rare earths.

Such phosphors are preferably distributed in a transparent epoxide casting resin. The phosphors preferably comprise or consist of luminescent pigments, and preferably have particle sizes of typically ≦25 μm, more preferably ≦20 μm, most preferably ≦20 μm, for example between 2 and 25 μm, 2 and 20 μm, 2 and 15 μm, 1 and 10 μm or even 1 and 4 μm. The phosphors preferably have a d50≦5 μm, preferably ≦4 μm, even more preferably ≦3 μm, for example between 1 and 5 μm, 2 and 5 μm, 1 and 4 μm or even 1 and 3 μm.

Phosphors mentioned by way of example, which are suitable for the present invention, comprise, without being restricted thereto, garnets that are doped with rare earths, for instance YAG:Ce (Y3Al5O12:Ce3+), or other garnets that are doped with rare earths, for instance Y3Ga5O12:Ce3+, Y(Al, Ga)5O12:Ce3+and Y(Al, Ga)5O12:Tb3+. Further phosphors which are suitable for the present invention may be selected from: thiogallates that are doped with rare earths, which comprise for example CaGa2S4:Ce3+, SrGa2S5:Ce3+, without being restricted thereto; or from aluminates that are doped with rare earths, which comprise for example YAlO3:Ce3+, YGaO3:Ce3+, Y(Al, Ga)O3:Ce3+, without being restricted thereto; from orthosilicates that are doped with rare earths, which comprise for example alkaline earth orthosilicate which is doped with divalent europium, with the formula a) (2-x-y)SrO.x(Bau, Cav)O.(1-a-b-c-d)SiO2.aP2O2 bAl2O3cB2O3dGeO2:yEu2+, where 0≦x≦1.6, 0.005<y<0.5, x+y<1.6, 0≦a, b, c, d<0.5 and u+v=1, or with the formula b) (2-x-y)BaO.x(Sru, Cav)O.(1-a-b-c-d)SiO2.aP2O5 bAl2O3cB2O3dGeO2:yEu2+, where 0.01≦x<1.6, 0.005<y<0.5, 0≦a, b, c, d<0.5 and u+v=1 and x.u≧0.4, or a mixture of formulae a) and b), without being restricted thereto; from oxyorthosilicates that are doped with rare earths, for instance M2SiO5:Ce3+ (M: Sc, Y, Sc), for example Y2SiO5:Ce3+, comprise, without being restricted thereto, in which case the yttrium in the yttrium compounds may also be replaced with scandium or lanthanum; or from phosphors with the following formula A3B5X12:M, where the variables are defined as A=Y, Ca, Sr; B=Al, Ga, Si; X=O, S and M=Ce3+, Tb3+.

A blue LED in the context of LEDs of each LED strip (2) of the lighting device (1) according to the invention is preferably based on a radiation-emitting semiconductor body, in particular having an active semiconductor layer or semiconductor layer sequence of GaxIn1-xN or GaxAl1-xN or consisting thereof, which emits electromagnetic radiation in the blue spectral range during operation. In combination with at least one phosphor as described here, preferably with at least one of the phosphors defined above, the blue LEDs which form the basis of each LED of each LED strip (2), as defined here, generate phosphor-converted white light.

The phosphors as defined above are preferably distributed in a casting composition which normally covers the active semiconductor layer, as described above, so that the phosphor-converted white LED as used according to the present invention is formed.

According to another aspect, the lighting device (1) according to the invention may furthermore comprise a control circuit on the main circuit board and/or a power supply unit and/or an adjustment device, preferably for each LED strip (2). In this context, the control circuit on the main circuit board and/or the power supply may independently operate and modulate the voltage delivered to each LED of each LED strip (2), so that the color temperature, the color coordinate and/or the light emission of each LED strip (2), if desired, can be adjusted separately.

Lighting devices (1) according to the invention, as described above, may for example be used in any product or generally a lamp device or lighting device, for example having an elongate or flat shape, for instance light chains, lighting devices in general, illuminated promotional devices, billboards, a lighting device (1) for private or industrial purposes, for example daytime running lights or tail lights of automobiles, etc., or any other suitable lighting device. Preferably, the LED strips (2) of the lighting devices (1) according to the invention are configured in such a way that they allow series connection, for example by one side of the LED strip (2) being provided with a connector to be received and on the opposite side of the LED strip (2) with a receiving connector.

According to another embodiment, the object of the present invention is furthermore achieved by a method for producing a white light-emitting LED device, the method preferably comprising the following steps:

a) selecting two outer LEDs (3) and one central LED (4) independently of one another from phosphor-converted white LEDs, preferably as defined here;

the distance of each of the color coordinates of the two outer LEDs from the color coordinate of the mixed light of the two outer LEDs and of the central LED being less than the distance of the color coordinate of the central LED from the color coordinates of the mixed light of the two outer LEDs and of the central LED; and

b) forming at least one LED strip (2) from the two outer LEDs (3) and the central LED (4), the LEDs preferably being in a linear arrangement such that each of the LED strips (2) comprises or consists of two outer LEDs (3) and one central LED (4).

In the method according to the invention, the LED strip (2) and the white light-emitting LED device are preferably as defined above for the lighting device (1) according to the invention. Each of the aspects discussed for the lighting device (1) according to the invention may be used and applied in the method according to the invention.

The present invention also relates to a lighting device (1) as defined here, which is obtained or can be obtained by the method as disclosed above for producing a white light-emitting LED device. Even more preferably, according to one particularly preferred aspect, the invention also relates to a method as defined above, wherein step b) of forming at least one LED strip (2) from the two outer LEDs (3) and the central LED (4) forms a lighting device (1) as originally defined according to the present disclosure of the invention.

According to another embodiment, the object of the present invention is achieved by the use of at least one strip, which consists of three light-emitting diodes (LEDs) in a linear arrangement in order to generate white light, wherein
a) each LED strip (2) comprises two outer LEDs (3) and one central LED (4);
b) each of the outer LEDs (3) and the central LED (4) are phosphor-converted white LEDs; and
c) the distance of each of the color coordinates of the two outer LEDs from the color coordinate of the mixed light of the two outer LEDs and of the central LED is less than the distance of the color coordinate of the central LED from the color coordinates of the mixed light of the two outer LEDs and of the central LED.

In the use according to the invention, the at least one strip which consists of three light-emitting diodes (LEDs) (LED strip (2)) is as defined above for the lighting device (1) according to the invention. Each of the aspects discussed for the lighting device (1) according to the invention may be applied similarly to the use according to the invention.

Unless otherwise indicated, all technical scientific terms, terms of the art and acronyms as used here have the meaning which is generally understood by anyone with normal knowledge of the art in the field.

After the present invention and its advantages have thus been described, it should be possible to understand that the various aspects and embodiments of the present invention, as disclosed here, are merely illustrative of specific ways of producing and using the invention, when the appended patent claims and the detailed description above are taken into account. Features of one aspect and one embodiment of the present invention, as disclosed here, may be combined with features of other aspects and embodiments of the present invention.

1. A lighting device (1) for generating white light, which comprises at least one strip (2) of three light-emitting diodes (LEDs) in a linear arrangement, wherein:
a) each LED strip (2) comprises two outer LEDs (3) and one central LED (4);
b) each of the two outer LEDs (3) and the central LED (4) are phosphor-converted white LEDs; and
c) the distance of each of the color coordinates of the two outer LEDs from the color coordinate of the mixed light of the two outer LEDs and of the central LED is less than the distance of the color coordinate of the central LED from the color coordinates of the mixed light of the two outer LEDs.

2. The lighting device (1) as claimed in claim 1, wherein the white light of each of the two outer LEDs (3) and of the central LED (4) has a color temperature which is selected independently from warm white light, cold white light and/or a color temperature between warm white light and cold white light, being a color temperature in the range of between about 2700 K and about 6500 K.

3. The lighting device (1) as claimed in claim 1, wherein the color coordinates of each of the two outer LEDs (3) and of the central LED (4) are selected independently of one another from a white color coordinate which lies on or in the vicinity of the Planckian curve (black body curve), a white color coordinate which lies inside a MacAdam ellipse, a white color coordinate which lies on or in the vicinity of the ANSI bin curve (ANSI 078.377-2008) or in a bin or a sub-bin thereof, or wherein the color coordinates of each of the two outer LEDs (3) and of the central LED (4) independently of one another have a white color coordinate according to the 1931 CIE (Commission internationale de l'eclairage) color system.

4. The lighting device (1) as claimed in claim 1, wherein the color coordinates of the two outer LEDs (3) are identical to one another or different to one another.

5. The lighting device (1) as claimed in claim 1, wherein the color coordinates of the two outer LEDs (3) are identical to one another and the color coordinates of the central LED (4) is selected from a bin, or a sub-bin, which according to the ANSI bin curve (ANSI C78.377-2008) is separated by 1 to 4 bins or sub-bins from the bin, or sub-bin, of the outer LEDs (3) or is in the same sub-bin.

6. The lighting device (1) as claimed in claim 1, wherein the color coordinates of the two outer LEDs (3) are not identical to one another and the color coordinates for the first and second outer LEDs (3) according to the ANSI bin curve (ANSI C78.377-2008) are separated by 1 or 2 sub-bins or are in the same sub-bin.

7. The lighting device (1) as claimed in claim 6, wherein the color coordinate of the central LED (4) is selected from a bin, or a sub-bin, which according to the ANSI bin curve (ANSI C78.377-2008) is separated by 1 to 4 bins or sub-bins from a bin, or sub-bin, of at least one of the outer LEDs (3) or is in the same sub-bin.

8. The lighting device (1) as claimed in claim 1, wherein the white color of the lighting device (1) is obtained by mixing the light of the two outer LEDs (3) and of the central LED (4) of each LED strip (2).

9. The lighting device (1) as claimed in claim 1, wherein the lighting device (1) comprises a plurality of LED strips (2), each of the LED strips (2) consisting of two outer LEDs (3) and one central LED (4), the number of LED strips (2) being in a range of between about 2 and 10000, between about 2 and 5000 or between about 2 and 1000.

10. The lighting device as claimed in claim 1, wherein the LED strips (2) are arranged in a linear form as an LED chain or in a two-dimensional or three-dimensional arrangement.

11. The lighting device (1) as claimed in claim 1, wherein each strip has a connector to be received on one side and a receiving connector on the opposite side of the LED strip (2).

12. The lighting device (1) as claimed in claim 1, wherein each LED strip (2) has a cover (5), which comprises a lens for each of the two outer LEDs (3) and the central LED (4).

13. The lighting device (1) as claimed in claim 1, wherein each LED strip (2) has a total internal reflection (TIR) lens.

14. The lighting device (1) as claimed in claim 1, wherein the LED strips (2) can be connected, by means of series connection, in the form of a chain of LED strips (2).

15. The lighting device (1) as claimed in claim 1, wherein the two outer LEDs (3) and the central LED (4) are selected independently of one another from LEDs which comprise a blue LED and at least one phosphor, the at least one phosphor being selected from the group consisting of: garnets that are doped with rare earths, including YAG, thiogallates that are doped with rare earths, aluminates that are doped with rare earths, orthosilicates that are doped with rare earths and oxyorthosilicates that are doped with rare earths.

16. The lighting device (1) as claimed in claim 1, wherein the lighting device (1) further comprises a control circuit on a main circuit board and/or a power supply unit and/or an adjustment device for each LED strip (2).

17. The lighting device (1) as claimed in claim 1, wherein the lighting device is used in a light chain, a lighting device, an illuminated promotional device, a billboard, a daytime running light for automobiles, or a tail light for automobiles.
